(19) United States
(12) Patent Application Publication
(10) Pub. No.: US 2005/0133085 A1
(43) Pub. Date: Jun. 23, 2005

(54) Lightweight solar battery module and method for producing the same

(75) Inventor: Keiji Shimada, Kitakatsuragi-gun (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/969,961

(22) Filed: Oct. 22, 2004

(30) Foreign Application Priority Data
Oct. 30, 2003 (JP) 2003-370722

(51) Int. Cl. H01L 31/00

(52) U.S. Cl. 136/255

(57) ABSTRACT

A lightweight solar battery module includes a solar cell sealed in a transparent adhesive layer, a transparent protective film disposed on a light-receiving surface side of the cell, and a heat-insulating sheet disposed on a non-light-receiving surface side of the cell.

### CROSS-REFERENCE TO RELATED APPLICATION

This application is related to Japanese Patent Application No. 2003-370722 filed on Oct. 30, 2003, whose priority is claimed under 35 USC § 119, the disclosure of which is incorporated by reference in its entirety.

### BACKGROUND OF THE INVENTION

1. Field of the Invention

The present invention relates to a lightweight solar battery module which can be suitably used as a power source for an airship.

2. Description of Related Art

Currently, stratospheric platforms, which are airships stationed in the stratosphere for a long period of time, are receiving attention as new wireless relay means and earth observation means that replace artificial satellites. Wireless relay systems using the stratospheric platforms are advantageous in that they have a larger coverage area per relay station than ground relay stations. In addition to that, they do not require space for setting relay stations and are hardly affected by natural disasters. The wireless relay systems using the stratospheric platforms are also advantageous over satellite transmission systems in that they have cheaper launching cost, shorter distance to relay stations and reduced transmission time.

The stratospheric platforms include, as a power supply system, a solar battery module and a battery for stably providing electricity for a long period of time, a regenerative fuel-cell or a combination of these power supplies. The solar battery module used in such an environment as the stratosphere needs to be light in weight and also weather resistant against ultraviolet rays and temperature difference between day and night.

When the temperature of the solar battery module is increased by sunlight and the heat is transferred to the stratospheric platforms (airships), the temperature of helium gas provided to the airships increases, making it difficult to control the lift of the airships. For this reason, the solar battery module and the outer surfaces of the airships need to be thermally insulated.

Currently, solar battery modules are widely used as a power source for housing and artificial satellites. However, because the stratospheric environment is severe, application of the solar battery modules in the stratosphere is difficult.

The air density in the stratosphere is about 1/15 to 1/20 of that on the ground and thus, the airships have a smaller lift in the stratosphere. The airships, therefore, need to be formed of a lightweight material. The solar battery modules, for example, need to have a weight per unit electric output of 3 g/W or less. However, commercially available solar battery modules for housing and solar racing cars have a weight per unit electric output of about 80 g/W to 100 g/W and about 10 g/W to 20 g/W, respectively, and they do not satisfy the requirements for the stratospheric application. Further, the solar battery modules for ground applications are designed for use in the above-ground environment and thus, can not withstand use in the stratospheric environment.

As the solar battery modules for artificial satellites, there have been manufactured flexible solar battery modules having a weight per unit electric output of about 3 g/W and using a Kapton® film as a substrate. The flexible solar battery modules, however, are very small in thickness and difficult to handle.

The modules for artificial satellites are adapted to an outer space environment severer in temperature and ultraviolet radiation than the stratospheric environment, and are not designed to cope with the stratospheric environment where the modules are affected by water adhesion and exposed to the atmosphere for long duration. Thus, the modules for artificial satellites can not withstand use in the stratospheric environment.

In Japanese Unexamined Utility Model Publication No. HEI 7(1995)-42518, there is disclosed a solar battery module having a reduced weight. In this solar battery module, a solar cell disposed on a substrate has its light-receiving surface covered with a light-transmissive adhesive layer and a light-transmissive protective film. The total thickness of the adhesive layer and the protective film is 100 μm or less.

Since this module is produced by bonding the cell and the adhesive layer by application of pressure with a roller, the thickness of the module is limited. Further, the module has projections and depressions formed on the substrate serving as a heat insulator, which causes small air bubbles to remain in the adhesive-film-like layers. The air bubbles become larger under the pressure in the stratosphere, resulting in a problem that the adhesive-film-like layers are peeled.

### SUMMARY OF THE INVENTION

The object of the present invention is to provide a lightweight solar battery module that can be used in the stratosphere.

In accordance with the present invention, there is provided a lightweight solar battery module comprising: a solar cell sealed in a transparent adhesive layer; a transparent protective film disposed on a light-receiving surface side of the cell; and a heat-insulating sheet disposed on a non-light-receiving surface side of the cell.

Further, the present invention provides a method for producing the lightweight solar battery module comprising the steps of: applying a transparent adhesive on a surface of each of the transparent protective film and the heat-insulating sheet; bonding the transparent protective film and the heat-insulating sheet with the solar cell sandwiched therebetween such that the transparent protective film is located on the light-receiving surface side of the cell and the heat-insulating sheet is located on the non-light-receiving surface side of the cell; and sealing the solar cell in the transparent adhesive.

### BRIEF DESCRIPTION OF THE DRAWINGS

FIG. 1 is a schematic sectional view of a lightweight solar battery module according to an embodiment of the present invention.

### DESCRIPTION OF THE PREFERRED EMBODIMENTS

A lightweight solar battery module according to the present invention includes: a solar cell sealed in a transparent adhesive layer, a transparent protective film disposed on a light-receiving surface side of the cell, and a heat-insulating sheet disposed on a non-light-receiving surface side of the cell.

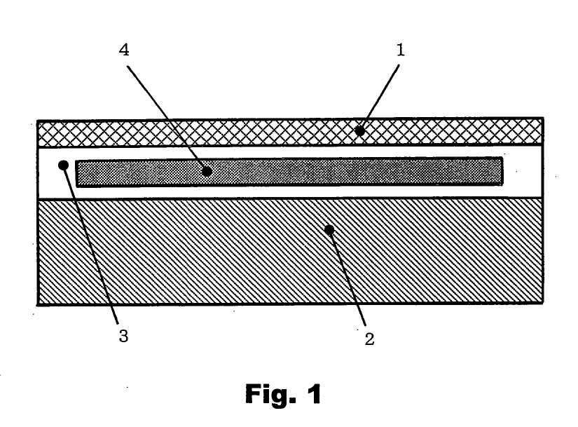

FIG. 1 is a schematic sectional view of a lightweight solar battery module according to an embodiment of the present invention. As shown, the module includes a solar cell 4, a transparent protective film 1 serving as a surface protective film for a light-receiving surface side of the cell 4, a heat-insulating sheet 2 serving as a substrate, and a transparent adhesive layer 3.

The following characteristics are required of the transparent protective film 1.

1-1. Low Density

Since the air density in the stratosphere is about 1/15 to 1/20 of that on the ground and thereby the lift of an airship decreases in the stratosphere, materials that make up the airship need to be light in weight. Thus, a material that forms the protective film 1 preferably has a density of 3 g/cm³ or less, and more preferably 2.5 g/cm³ or less.

1-2. Capable of Being Thinned

For the same reasons as described above in 1-1, the protective film 1 needs to be small in thickness in order reduce the weight of the solar battery module. Thus, the material that forms the protective film 1 needs to be capable of being thinned while maintaining the mechanical strength which allows the film to endure the use environment. The protective film 1 preferably has a thickness of about 5 μm to 30 μm, and more preferably 10 μm to 20 μm.

1-3. High Light-Transmittance and Small Refractive Index

To achieve a high-output solar battery module, the protective film 1 preferably has a high light-transmittance and a small refractive index. More specifically, the protective film 1 has an average light-transmittance of not less than 80%, and preferably not less than 90% with respect to sensible wavelengths of a solar battery (for example, 300 nm to 1200 nm in the case of a silicon solar battery). The protective film 1 has a refractive index of about 1 to 1.6, and preferably 1.2 to 1.4.

1-4. Less Prone to Deterioration from Long Exposure to the Outdoors (Particularly, Ultraviolet Rays)

In the stratosphere, the solar battery module is utilized in an environment of severe temperature and ultraviolet rays, and is affected by adhesion of water and exposure to the atmosphere for a long period of time. Thus, the protective film 1 needs to be formed of a material that can withstand use in such an environment.

1-5. Resistance to Temperature Change from About −50° C. to 100° C.

For the same reasons as described above in 1-4, the solar battery module needs to have stability in a wide range of temperatures. Thus, the protective film 1 is heat-resistant to temperatures of −50° C. to 100° C., and preferably −60° C. to 110° C.

Examples of the material that satisfies the aforesaid requirements are: polyvinylidene chloride (PVDC); fluorine-containing resins such as polytetrafluoroethylene (PTFE), polytrifluorochloroethylene (PTFCE), polyvinylidene fluoride (PVDF), a copolymer of tetrafluoroethylene and perfluoroalkylvinylether (PFA), and a copolymer of tetrafluoroethylene and hexafluoropropylene (FEP); and acryl-containing resins such as polymethyl methacrylate (PMMA), and copolymers of methyl methacrylate and monomers that improve heat-resistance such as α-methylstyrene, maleic anhydride and maleimide-containing monomers. All of these materials are preferably used, and among those recited above, PVDC, PFE and FEP are particularly preferable. In Table 1, representative values of properties of the above-mentioned materials are shown. The materials mentioned above may be used alone as a single-layer film, or in combination as a multilayer film.

In the present invention, the term “fluorine-containing resins” implies thermoplastic resins having a carbon-fluorine bond in their molecules, and the term “acryl-containing resins” implies resins obtained by polymerizing acrylic acid (methacrylic acid) and its derivative.

TABLE 1

| | | Polyvinylidene | |
|---|---|---|---|
| Property | | chloride | Fluororesin (FEP) |
| Density | g/cm³ | 1.7 | 2.15 |
| Light-transmittance | % | 92 | 95 |
| Refractive Index | | 1.61 | 1.34 |
| Heat-resistance | ° C. | −60 to 140 | −200 to 200 |

The following characteristics are required of the heat-insulating sheet 2.

2-1. Excellent Heat-Insulating Properties

Where the solar battery module is utilized as a power source for an airship, the solar battery module and the outer surface of the airship need to be thermally insulated from each other. This is because, when the heat of the solar battery module is transferred to helium gas provided to the airship, lift control of the airship becomes difficult. Thus, a material that forms the heat-insulating sheet 2 preferably has a thermal conductivity of 0.1 (W/m/K) or less, and more preferably 0.05 (W/m/K) or less.

2-2. Low Density

For the same reasons as described above in 1-1, the heat-insulating sheet 2 needs to be light in weight in order to reduce the weight of the solar battery module. Thus, the heat-insulating sheet 2 is preferably formed of a foam. Because the weight of the solar battery module increases when the transparent adhesive layer 3 permeates into the heat-insulating sheet 2, it is particularly preferable that the foam of the heat-insulating sheet 2 has a closed-cell structure but not an open-cell structure. The density of the sheet 2 is preferably 40 kg/m³ or less, and more preferably 30 kg/m³ or less.

2-3. Less Prone to Deterioration from Long Exposure to the Outdoors (Particularly, Ultraviolet Rays)

For the same reasons as described above in 1-4, the heat-insulating sheet 2 needs to be formed of a material that can endure adhesion of water and exposure to the atmosphere for a long period of time.

2-4. Resistance to Temperature Change from About −50° C. to 100° C.

For the same reasons as described above in 1-4, the solar battery module needs to have stability in a wide range of temperatures. Thus, the heat-insulating sheet 2 is heat-resistant to temperatures of −50° C. to 100° C., and preferably −60° C. to 110° C. As a material that satisfies the aforesaid requirements, phenol resin foams having a closed-cell structure are particularly preferable. In Table 2, representative values of properties of the phenol resin foams are shown.

Low-density foams such as polystyrene and polyurethane are liable to deteriorate from ultraviolet rays and have a lower heat-resistance than phenol resin foams. This makes the low density foams unsuitable for the solar battery module used as a power source for an airship. Low-density spongy foams such as polyimide have the open-cell structure and thus, are very soft and hardly have stiffness. This makes difficult to handle the low-density spongy foams and produce large panels from such foams. Thus, the low-density spongy foams are not suitable for the solar battery module used as a power source for an airship.

The heat-insulating sheet 2 has a thickness of, for example, about 5,000 μm to 20,000 μm.

TABLE 2

| | | Phenol resin foam |
|---|---|---|
| Property | | (open-cell structure) |
| Density | kg/m³ | 27 |
| Heat-resistance | ° C. | −200 to 130 |
| Heat-conductivity | W/m/K | 0.021 (20° C.) |

The same characteristics 1-1 to 1-5 as the transparent protective film 1 are required of the transparent adhesive layer 3. As a material that satisfies such requirements, a silicon resin is particularly preferable.

In solar battery panels for ground (housing) and solar racing car applications, a copolymer of ethylene and vinyl acetate (EVA) is usually used as an adhesive. This copolymer, however, is difficult to be thinned and liable to be discolored by moisture absorption. Thus, the EVA is not suitable for the solar battery module used as a power source for an airship.

The thickness of the transparent adhesive layer 3 between the solar cell 4 and each of the protective film 1 and the heat-insulating sheet 2 is about 10 μm to 50 μm.

The type of the solar cell 4 is not particularly limited. The solar cell 4 may be, for example, a known solar cell which includes a semiconductor substrate having a pn junction and electrodes sandwiching the substrate. The cell 4 may be a solar battery string having a plurality of solar cells connected to each other. Where a silicon monocrystalline cell is adopted, for example, the thickness thereof may be about 30 μm to 100 μm.

The lightweight solar battery module according to the present invention may be produced by applying a transparent adhesive on a surface of each of the transparent protective film and the heat-insulating sheet; bonding the transparent protective film and the heat-insulating sheet with the solar cell sandwiched therebetween such that the transparent protective film is located on the light-receiving surface side of the cell and the heat-insulating sheet is located on the non-light-receiving surface side of the cell; and sealing the solar cell in the transparent adhesive. The sealing of the solar cell is preferably carried out in a vacuum so that the transparent adhesive serving as the transparent adhesive layer is prevented from containing air bubbles.

A plurality of said solar cells may be connected to form a solar battery string. Then, the solar battery string may be sandwiched between the heat-insulating sheet and the transparent protective film on which a transparent adhesive is applied, and the heat-insulating sheet and the protective film are bonded to form a solar battery module shown in FIG. 1.

The materials shown in Table 3, that is, a transparent protective film having a size of 13 cm×13 cm, six pieces of solar cell having a size of 4 cm×6 cm (light-conversion efficiency of 13.5% at AM 0), and a heat-insulating sheet having a size of 13 cm×13 cm are used to form the solar battery module according to the present invention. The module thus produced has an electric output of 2.63 W and is calculated, from its weight of 7.73 g, to have a weight per unit electric output of 2.94 g/W.

TABLE 3

| | | Density | Thickness | Weight |
|---|---|---|---|---|
| | Constituent/Material | (g/cm³⁾ | (μm) | (g) |
| Transparent | Fluororesin | 2.15 | 15 | 0.55 |
| protective film | | | | |
| Solar cell | Si substrate | — | 60 | 2.93 |
| | Rear electrode | — | 2 | |
| Transparent | Silicon resin | 1.05 | 30 × 2 | 1.06 |
| adhesive layer | | | | |
| Heat-insulating | Phenol resin foam | 0.027 | 7,000 | 3.19 |
| sheet | | | | |
| Total | | | (1 cm) | 7.73 |

According to the present invention, provided is a solar battery module which is light in weight and easy to handle. More particularly, there is provided a lightweight solar battery module for stratospheric platforms.

1. A lightweight solar battery module comprising:
a solar cell sealed in a transparent adhesive layer;
a transparent protective film disposed on a light-receiving surface side of the cell; and
a heat-insulating sheet disposed on a non-light-receiving surface side of the cell.

2. A lightweight solar battery module according to claim 1, wherein the transparent protective film is formed of a material having a density of 3 g/cm³ or less, an average light-transmittance of 80% or higher with respect to sensible wavelengths of the cell, a refractive index of 1 to 1.6, and heat-resistance from −50° C. to 100° C. inclusive.

3. A lightweight solar battery module according to claim 1, wherein the transparent protective film is a film formed of a material selected from the group consisting of polyvinylidene chloride, a fluorine-containing resin and an acryl-containing resin, or a multilayer film thereof.

4. A lightweight solar battery module according to claim 1, wherein the transparent protective film has a thickness of 5 μm to 30 μm.

5. A lightweight solar battery module according to claim 1, wherein the heat-insulating sheet is formed of a material having a heat-conductivity of 0.1 (W/m/K) or less, a density of 40 kg/m³ or less, and heat-resistance from −50° C. to 100° C. inclusive.

6. A lightweight solar battery module according to claim 1, wherein the heat-insulating sheet is formed of a phenol resin foam having a closed-cell structure.

7. A lightweight solar battery module according to claim 1, wherein the heat-insulating sheet has a thickness of 5,000 82 m to 20,000 μm.

8. A lightweight solar battery module according to claim 1, wherein the transparent adhesive layer is formed of a material having a density of 3 g/cm³ or less, an average light-transmittance of 80% or less with respect to sensible wavelengths of the cell, a refractive index of 1 to 1.6, and heat-resistance from −50° C. to 100° C. inclusive.

9. A lightweight solar battery module according to claim 1, wherein the transparent adhesive layer is formed of a silicon resin.

10. A lightweight solar battery module according to claim 1, wherein the thickness of the transparent adhesive layer between the solar cell and each of the protective film and the heat-insulating sheet is 10 μm to 50 μm

11. A lightweight solar battery module according to claim 1, wherein the module has a weight per unit electric output of 3 g/W or less.

12. A lightweight solar battery module according to claim 1, wherein the module is utilized as a power source for a stratospheric platform.

13. A method for producing a lightweight solar battery module comprising a solar cell sealed in a transparent adhesive layer, a transparent protective film disposed on a light-receiving surface side of the cell, and a heat-insulating sheet disposed on a non-light-receiving surface side of the cell, the method comprising the steps of:
applying a transparent adhesive on a surface of each of the transparent protective film and the heat-insulating sheet;
bonding the transparent protective film and the heat-insulating sheet with the solar cell sandwiched therebetween such that the transparent protective film is located on the light-receiving surface side of the cell and the heat-insulating sheet is located on the non-light-receiving surface side of the cell; and
sealing the solar cell in the transparent adhesive.

14. A method for producing a lightweight solar battery module according to claim 13, wherein the solar cell is sealed in the transparent adhesive in a vacuum.

15. A method for producing a lightweight solar battery module according to claim 13, wherein a solar battery string formed by connecting a plurality of said solar cells is used in place of the solar cell.
